(19) United States
(12) Patent Application Publication
(10) Pub. No.: US 2009/0032107 A1
(43) Pub. Date: Feb. 5, 2009

(54) ORGANIC SOLAR CELL USING CONDUCTIVE POLYMER TRANSPARENT ELECTRODE AND FABRICATING METHOD THEREOF

(75) Inventors: DONG SOO KIM, DAEJEON (KR); KANG DAE KIM, BUSAN (KR); CHUNG HWAN KIM, SEOUL (KR); BYUNG OH CHOI, DAEJEON (KR); HYUN EUI LIM, DAEJEON (KR)

Correspondence Address: HOLME ROBERTS & OWEN LLP, 1700 LINCOLN STREET, SUITE 4100, DENVER, CO, 80203, US

(73) Assignee: KOREA INSTITUTE OF MACHINERY & MATERIALS, Daejeon (KR)

(21) Appl. No.: 12/184,609

(22) Filed: Aug. 1, 2008

(30) Foreign Application Priority Data
Aug. 3, 2007 (KR) 10-2007-0078154
Apr. 30, 2008 (KR) 10-2008-0040518

(51) Int. Cl. H01L 31/0256; H01L 31/18

(52) U.S. Cl. 136/263; 427/485

(57) ABSTRACT

The present invention relates to an organic solar cell made of a transparent conductive polymer electrode and a fabricating method thereof. An anode electrode is formed on a substrate, a photoactive layer is formed on the anode electrode, and a cathode electrode is then formed on the photoactive layer. The anode electrode is formed by stacking conductive polymer particles by an electrostatic spray printing method, and a micro pattern is formed on the substrate before forming the anode electrode. The micro pattern is formed by hot embossing, the photoactive layer is formed by gravure printing or spin coating, and the cathode electrode is formed by screen print or evaporation deposition. A series of processes for fabricating an organic solar cell is performed using a roll-to-roll process.

### BACKGROUND OF THE INVENTION

1. Field of the Invention

The present invention relates to a solar cell, and more particularly, to a method of fabricating an organic solar cell, wherein an anode electrode is formed by stacking conductive polymer particles by an electrostatic spray printing method.

2. Description of the Related Art

It is becoming increasingly important to develop next-generation clean energy sources due to serious environmental pollution and fossil energy exhaustion. Solar cells produce little pollution, utilize infinite resource and have a semi-permanent lifetime, thus it is expected that solar cells can serve as an energy source for solving future energy problems.

Currently, silicon solar cells are used in 90% of solar cell applications. However, since the conversion efficiency of silicon solar cells is only 20% or so, the cost of generating electricity with silicon solar cell is higher than other energy sources. Moreover, the cost of fabricating solar cells has been increased due to supply-demand problems of silicon raw materials and silicon substrates since 2000. Therefore, solar cells have problems with raw material supply-demand and fabrication cost in addition to low efficiency.

Organic solar cells have recently come into the spotlight as a way to solve the problems of silicon solar cells, and many studies on organic solar cells have been conducted. In an organic solar cell, a photoactive layer is formed from an organic material such as a polymer between anode and cathode electrodes. In a conventional organic solar cell, indium tin oxide (ITO), which is transparent and electrically conductive is mainly used as the anode electrode.

However, a vacuum process for manufacturing an electrode thin film is required for the anode electrode made of a metal oxide material such as ITO. Therefore, the cost of manufacturing the anode electrode is high, and the anode electrode is fragile and therefore not suitable for a flexible solar cell.

In order to solve the problems of manufacturing a transparent electrode made of metal oxide, a technique for fabricating an electrode made of a transparent conductive polymer material has recently been studied. In the corresponding technical field, only a material for a transparent electrode has been developed, and studies on process development are insufficient.

Also, there is a disadvantage in that the conventional transparent conductive polymer electrode has little electrical conductivity. In order to be equal to the conventional metal oxide transparent electrode, the surface resistance should be in the order of a few tens of Ω/sq. However, the surface resistance of the conventional transparent conductive polymer electrode is a few hundred Ω/sq to several kΩ/sq.

### SUMMARY OF THE INVENTION

Accordingly, an object of the present invention is to provide an organic solar cell and a fabricating method thereof for solving problems of a silicon solar cell, wherein an a transparent anode electrode is made of a conductive polymer material instead of a conventional metal oxide.

Another object of the present invention is to provide an organic solar cell and a fabricating method thereof using a transparent conductive polymer electrode which is easily formed on a plastic substrate and has excellent electrical characteristics.

A further object of the present invention is to provide an organic solar cell and a fabricating method thereof suitable for a roll-to-roll process.

To achieve the the objects of the present invention, a method of fabricating an organic solar cell according to the present invention comprises the steps of forming an anode electrode on a substrate; forming a photoactive layer on the anode electrode; and forming a cathode electrode on the photoactive layer, wherein the step of forming an anode electrode is performed by stacking conductive polymer particles on the substrate by an electrostatic spray printing method.

In the method of fabricating an organic solar cell according to the present invention, the conductive polymer particle is preferably polyethylenedioxythiophene polystyrenesulfonate, and may be any one of polyethylenedioxythiophene, polyacetylene, polypyrrole, polythiophene and polyaniline. In addition, the conductive polymer particles may be sprayed in the form of a conductive polymer ink, wherein the conductive polymer ink is mixed with an additive and contained in a capillary of an electrostatic spray printing unit. It is preferable that the additive be polyalcohol. The substrate may be a plastic substrate.

The method of fabricating an organic solar cell according to the present invention may further comprise a step of forming a micro pattern having a concavo-convex portion on a surface of the substrate before the step of forming an anode electrode. In such a case, the step of forming a micro pattern may be performed by hot embossing.

In the method of fabricating an organic solar cell according to the present invention, the step of forming a photoactive layer may be performed by gravure printing or spin coating. The step of forming a cathode electrode may be performed by screen print or evaporation deposition.

In addition, the steps of forming a micro pattern, an anode electrode, a photoactive layer and a cathode electrode may be consecutively performed by a roll-to-roll process while the substrate is transferred.

The present invention provides an organic solar cell fabricated by the aforementioned fabrication method.

### BRIEF DESCRIPTION OF THE DRAWINGS

FIGS. 1a to 1d are sectional views illustrating an organic solar cell and a fabricating method thereof according to an embodiment of the present invention;

FIG. 2 is a view conceptually illustrating an electrostatic spray printing method used in a method of fabricating a transparent conductive polymer electrode; and

FIG. 3 is schematic view illustrating a roll-to-roll fabrication method of an organic solar cell according to an embodiment of the present invention.

### DETAILED DESCRIPTION OF THE INVENTION

Hereinafter, preferred embodiments of the present invention will be described in detail with reference to the accompanying drawings. Technical descriptions that are well known in the art to which the present invention pertains and are not directly connected with the present invention will be omitted as much as possible from the descriptions of the embodiments. This is for the purpose of communicating the features of the present invention more clearly by omitting unnecessary descriptions.

In addition, some components in the drawings are exaggerated, omitted, or schematically shown, and the dimensions of the actual components are not entirely reflected in the respective components shown in the drawings. Like reference numerals indicate like elements throughout the specification and drawings.

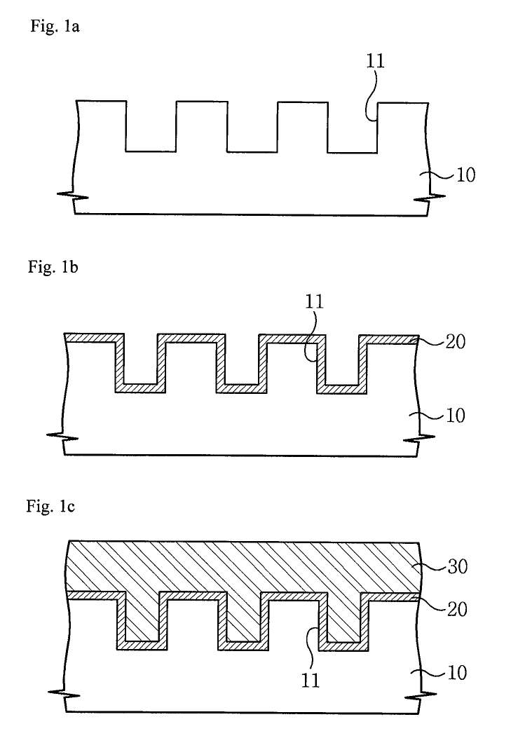

FIGS. 1a to 1d are sectional views illustrating an organic solar cell and a fabricating method thereof according to an embodiment of the present invention.

Referring to FIG. 1a, a substrate 10 for a solar cell is prepared, and a surface of the substrate 10 is then processed. For example, the substrate 10 is a plastic substrate, which is made of a material, such as polyethylene naphthalate (PEN), polyethylene terephthalate (PET), polymethyl methacrylate (PMMA), polycarbonate (PC), polyethersulfone (PES), polyimide (PI), and the like. However, the substrate 10 material is not necessarily limited to plastic but may be other various materials.

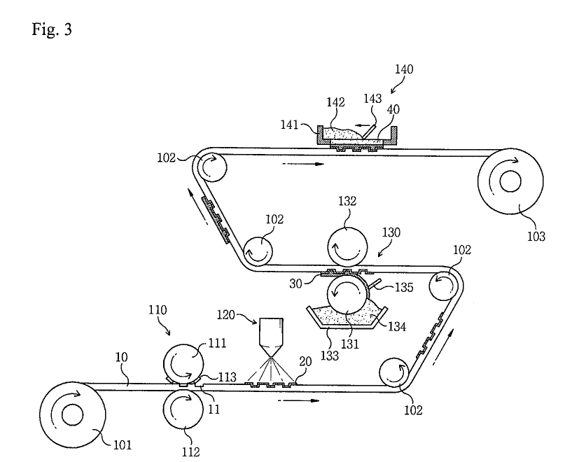

The surface of the substrate 10 is processed by hot embossing to form a micro pattern 11 with a concavo-convex portion. The hot embossing will be described later with reference to FIG. 3. The micro pattern 11 increases the contact area between an anode electrode 20 (see FIG. 1b) and a photoactive layer 30 (see FIG. 1c), which will be subsequently formed, thereby increasing the effective area per unit area of the solar cell. That is, the micro pattern 11 does not increase the size of the solar cell but increase the effective area thereof into which light is absorbed, thereby enhancing photoelectric conversion efficiency. However, the micro pattern 11 may not be formed depending on the circumstances. In this case, the technical spirit of the present invention will not be changed.

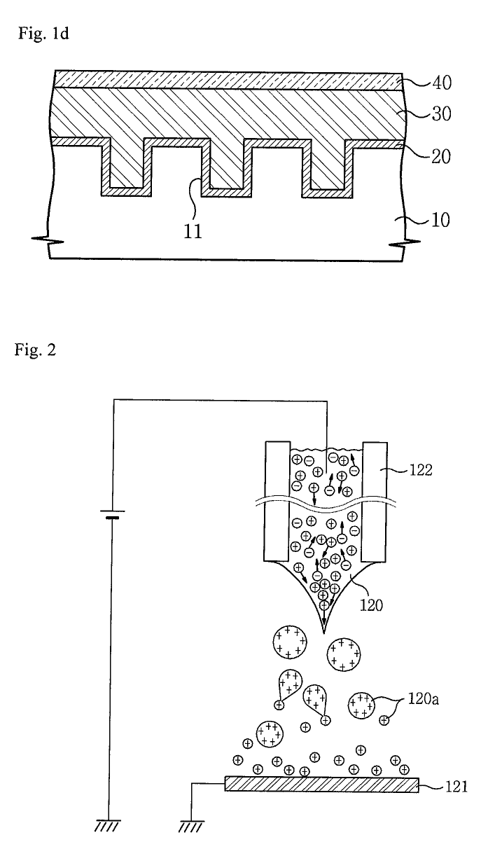

Subsequently, an anode electrode 20 is formed on the substrate 10 as shown in FIG. 1b. The anode electrode 20 is a transparent electrode having transparency and electrical conductivity, and is made of a conductive polymer material. A process of forming the anode electrode 20 is performed by an electrostatic spray printing method, which will be described in detail with reference to FIG. 2. The anode electrode 20 is cured by a low-temperature thermosetting method.

Then, a photoactive layer 30 is formed on the anode electrode 20 as shown in FIG. 1c. The photoactive layer 30 is formed of an ink material in which hole and electron acceptors are mixed by gravure printing or spin coating. The gravure printing will be described later with reference to FIG. 3.

As the hole acceptor, a polythiophene derivative such as poly 3-hexylthiophene (P3HT) or a conductive conjugated polymer such as poly-para-phenylene vinylene (PPV) can be used. As the electron acceptor, a fullerene derivative such as [6,6]-phenyl-C61 butyric acid methyl ester (PCBM) can be used. The hole and electron acceptors should be formed of an ink material in which they are sufficiently mixed each other so that holes and electrons produced by light can be collected into the anode electrode 20 and a cathode electrode 40 (see FIG. 1d) without loss. Like the anode electrode 20, the photoactive layer 30 is cured by a low-temperature thermosetting method.

Subsequently, a cathode electrode 40 is formed on the photoactive layer 30 as shown in FIG. 1d. The cathode electrode 40 is formed of a conductive material such as Al or Ag by screen print or evaporation deposition. The screen print will be described later with reference to FIG. 3. In addition to Al or Ag, at least one selected from the group of consisting of Au, Zn, Cu, C, carbon nano tube and conductive polymer may be a cathode electrode (40) material. The cathode electrode 40 is also cured by a low-temperature thermosetting method.

The method of forming the anode electrode 20, which has not been described with reference to FIG. 1b, will be described with reference to FIG. 2. FIG. 2 is a view conceptually illustrating an electrostatic spray printing method used in a method of fabricating a transparent conductive polymer electrode.

As shown in FIG. 2, the electrostatic spray printing method is a technique in which charged conductive polymer particles 120a are guided toward the substrate 121 by an electric field formed between a substrate 121 and a capillary 122 and therefore printed on the substrate 121.

Specifically, a conductive polymer ink 120 is contained in the capillary 122, and an additive for improving electrical conductivity is added to the conductive polymer ink 120, which will be described in detail later. The substrate 121, on which a transparent conductive polymer electrode will be formed, is disposed so as to be spaced apart from the capillary 122 by a predetermined distance. If a high voltage is applied to the conductive polymer ink 120 contained in the capillary 122 in a state where the substrate 121 is grounded (practically, a substrate holder for supporting the substrate is grounded), an extremely large electric field is generated at an end of the capillary 122 by an electric field concentration effect.

The electric field concentrated at the end of the capillary 122 separates a conductive polymer material into positive and negative ions to produce ionized particles, i.e., charged particles 120a. The charged particles 120a are concentrated on a surface of the conductive polymer ink 120 and the surface of the conductive polymer ink 120 becomes unstable. Therefore the charged particles 120a are jet-sprayed from the capillary 122. The sprayed micro droplets are guided toward the substrate 121 by the electric field and stacked on the substrate 121 in the form of micronized particles.

Using the electrostatic spray printing method, the anode electrode 20 of the organic solar cell shown in FIG. 1b can be formed of a conductive polymer material instead of a conventional metal oxide. Particularly, the anode electrode 20 can be easily formed even when the substrate 10 of the organic solar cell is a plastic substrate. In addition, the conductive polymer electrode 20 formed as described above has similar electrical characteristics to a conventional metal oxide and has excellent film uniformity and density.

Meanwhile, as the conductive polymer material used for the anode electrode 20 of the organic solar cell, polyethylenedioxythiophene (PEDOT), polyacetylene, polypyrrole, polythiophene, polyaniline and the like can be used. Preferably, as the conductive polymer material, polyethylenedioxythiophene polystyrenesulfonate (PEDOT:PSS) is used. However, the present invention is not necessarily limited thereto, and any transparent and conductive polymer materials may be applied. For example, polyalcohol such as glycerol or sorbitol can be used as the additive.

The method of fabricating an organic solar cell according to the present invention may be consecutively performed using a roll-to-roll (R2R) process. Hereinafter, the method of fabricating an organic solar cell will be described with reference to FIG. 3. FIG. 3 is schematic view illustrating an R2R fabrication method for an organic solar cell according to an embodiment of the present invention.

First of all, in order to fabricate an organic solar cell by the R2R process, a substrate 10 should be a flexible plastic substrate. The substrate 10 is provided in a state where it is wound around a discharge roller 101, completely subjected to a series of fabrication processes, and then, wound around a storage roller 103. A plurality of transfer rollers 102 may be installed between the discharge roller 101 and the storage roller 103.

A process of forming a micro pattern 11 is performed on the substrate 10, which is supplied from the discharge roller 101, through a hot embossing unit 110. The hot embossing unit 110 comprises upper and lower rollers 111 and 112, wherein press projections 113 corresponding to the micro pattern 11 are formed on a surface of the upper roller 111. The upper and lower rollers 111 and 112 press the substrate 10 while being engaged with each other and rotated, and thus, the micro pattern 11 is formed on a surface of the substrate 10 by the press projections 113.

Subsequently, an anode electrode 20 is formed on the substrate 10 with the micro pattern 11 through an electrostatic spray printing unit 120. The electrostatic spray printing unit 120 includes the capillary 122 described with reference to FIG. 2. The electrostatic spray printing unit 120 further includes an electrode (not shown) which is inserted into an upper portion of the capillary 122 and connected to a power source to apply a high voltage to a conductive polymer aqueous dispersion.

Then, a photoactive layer 30 is formed on top of the substrate 10, on which the anode electrode 20 is formed, through a gravure printing unit 130. The gravure printing unit 130 comprises a gravure cylinder 131, a press roller 132, an ink container 133, gravure ink 134 and a doctor blade 135. The gravure cylinder 131 is rotated while the gravure cylinder 131 is partially sunk in the ink container 133 containing the gravure ink 134. When gravure cylinder 131 starts to rotate, the gravure ink 134 in the ink container 133 is provided toward the substrate 10. At this time, the doctor blade 135 adjusts the amount of the gravure ink 134 so that it is supplied at a predetermined amount. The photoactive layer 30 is formed on the anode electrode 20 of the substrate 10 by the gravure ink 134 supplied by the gravure cylinder 131.

Thereafter, a cathode electrode 40 is formed on top of the substrate 10, on which the photoactive layer 30 is formed, through a screen print unit 140. The screen print unit 140 comprises a screen 141, paste 142 and a squeeze 143. If the paste 142 is pushed through the screen 141 by means of the squeeze 143 in a state where the paste 142 is supplied on the screen 141, the cathode electrode 40 is formed on the photoactive layer 30.

As described above, the present invention provides an organic solar cell and a fabricating method thereof for solving the problems of a silicon solar cell, by producing a transparent anode electrode made of a conductive polymer material instead of a conventional metal oxide.

Particularly, according to the present invention, a transparent anode electrode is easily formed on a plastic substrate using a conductive polymer material, and such a transparent conductive polymer anode electrode has electrical characteristics equal to a conventional metal oxide anode electrode.

Furthermore, according to the present invention, there is provided an organic solar cell and a fabricating method thereof suitable for a roll-to-roll process, so that productivity can be increased and the fabrication cost can be reduced.

An organic solar cell and a fabricating method thereof using a transparent conductive polymer electrode according to the present invention has been described through the above embodiments. Although the preferred embodiments of the present invention are disclosed in the specification and drawings and specific terminology are used, these are used as general meanings only for explaining the technical meaning of the present invention with ease and helping understand the present invention. They do not intend to limit the scope of the present invention. In addition to the embodiments disclosed herein, it will be apparent to those skilled in the art that modifications can be made thereto on the basis of the technical spirit of the present invention.

1. A method of fabricating an organic solar cell, comprising the steps of:
forming an anode electrode on a substrate;
forming a photoactive layer on the anode electrode; and
forming a cathode electrode on the photoactive layer,
wherein the step of forming the anode electrode is performed by stacking conductive polymer particles on the substrate by an electrostatic spray printing method.

2. The method of claim 1, wherein the conductive polymer particles are polyethylenedioxythiophene polystyrenesulfonate.

3. The method of claim 1, wherein the conductive polymer particles are any one of polyethylenedioxythiophene, polyacetylene, polypyrrole, polythiophene and polyaniline.

4. The method of claim 1, wherein the conductive polymer particles are sprayed in the form of a conductive polymer ink, the conductive polymer ink being mixed with an additive and being contained in a capillary of an electrostatic spray printing unit.

5. The method of claim 4, wherein the additive is polyalcohol.

6. The method of claim 1, wherein the substrate is a plastic substrate.

7. The method of claim 1, further comprising a step of forming a micro pattern having a concavo-convex portion on a surface of the substrate before the step of forming the anode electrode.

8. The method of claim 7, wherein the step of forming the micro pattern is performed by hot embossing.

9. The method of claim 1, wherein the step of forming the photoactive layer is performed by gravure printing or spin coating.

10. The method of claim 1, wherein the step of forming the cathode electrode is performed by screen print or evaporation deposition.

11. The method of claim 7, wherein the steps of forming the micro pattern, the anode electrode, the photoactive layer and the cathode electrode are consecutively performed by a roll-to-roll process while the substrate is transferred.

12. An organic solar cell fabricated by the fabrication method comprising the steps of claim 1.
